(19) United States
(12) Patent Application Publication
(10) Pub. No.: US 2015/0325585 A1
(43) Pub. Date: Nov. 12, 2015

(54) METHOD FOR FORMING THREE-DIMENSIONAL MEMORY AND PRODUCT THEREOF

(71) Applicant: MACRONIX International Co., Ltd., Hsinchu (TW)

(72) Inventor: Chi-Sheng Peng, Hsinchu (TW)

(73) Assignee: MACRONIX International Co., Ltd., Hsinchu (TW)

(21) Appl. No.: 14/275,598

(22) Filed: May 12, 2014

(51) Int. Cl. H01L 27/115

(52) U.S. Cl. CPC H01L 27/11568; H01L 27/11582

(57) ABSTRACT

A method for forming a 3D memory is described. A stacked structure including alternately arranged semiconductor layers and insulating layers is formed on a substrate. The stacked structure is patterned into linear stacks in a row direction, wherein each linear stack includes alternately arranged channel layers and linear insulators. An insulating material is filled in between the linear stacks. Damascene openings are formed in the insulating material between each two neighboring linear stacks, wherein each damascene opening exposes a portion of each of the opposite sidewalls of all the channel layers of two neighboring linear stacks. A charge trapping layer is formed. Word lines are formed in the damascene openings.

### BACKGROUND OF THE INVENTION

1. Field of Invention

This invention relates to a semiconductor process and a product formed thereby, and particularly relates to a method for forming a three-dimensional (3D) memory, and a 3D memory formed with the method.

2. Description of Related Art

As the demand for storage subsystems of electronic products is increased, the standard for the read/write speeds or capacities of products is higher, so high-capacity related products have become the mainstream in the industry. Therefore, 3D memory, especially 3D vertical-gate (VG) NAND flash memory, has been developed recently.

In a conventional 3D memory process, a stacked structure including alternately arranged semiconductor layers and insulating layers is formed and patterned into linear stacks in a row direction, a blanket charge trapping layer is formed over the resultant, and then a conductive layer is formed filling in between the linear stacks and patterned in a column direction into a 2D array of vertical word lines between the linear stacks.

However, since the gaps between the linear stacks have a high aspect ratio, the patterning etching of the conductive layer deep in the gaps is difficult. Therefore, the conventional VG NAND memory easily suffers from serious word-line bridging issue.

### SUMMARY OF THE INVENTION

In view of the foregoing, this invention provides a method for forming a 3D memory, which is capable of preventing bridging of vertical word-lines.

This invention also provides a 3D memory formed with the same method.

The method for forming a 3D memory of this invention is described below. A stacked structure, which includes a plurality of semiconductor layers and a plurality of insulating layers arranged alternately, is formed on a substrate. The stacked structure is patterned into a plurality of linear stacks in a row direction, wherein each linear stack includes a plurality of channel layers and a plurality of linear insulators arranged alternately, the channel layers are defined from the semiconductor layers, and the linear insulators are defined from the insulating layers. An insulating material is filled in between the linear stacks. A plurality of damascene openings is formed in the insulating material between each two neighboring linear stacks, wherein each damascene opening exposes a portion of each of the opposite sidewalls of all the channel layers of two neighboring linear stacks. A charge trapping layer is formed. A plurality of word lines is formed in the damascene openings.

In an embodiment of the above method, a linear hard mask part is left on each linear stack, a plurality of column-direction trenches contiguous with the damascene opening is formed through the row-direction linear hard mask parts during the definition of the damascene opening, and then the trenches are also filled by the same material of the word lines, in the step of forming the word lines, to form a plurality of interconnect lines each connected with a column of word lines.

In another embodiment, after the word lines are formed, a plurality of contact plugs and a plurality of interconnect lines in a column direction are formed over the word lines, wherein each interconnect line is electrically connected with a column of word lines via a column of contact plugs.

In an embodiment, the charge trapping layer is formed in the damascene openings after the damascene openings are formed but before the word lines are formed. In another embodiment, the charge trapping layer is formed after the stacked structure is patterned into the linear stacks but before the insulating material is filled in between the linear stacks.

The 3D memory of this invention includes a plurality of linear stacks in a row direction, an insulating material between the linear stacks, a charge trapping layer and a plurality of word lines. Each linear stack includes a plurality of channel layers and a plurality of linear insulators arranged alternately. The insulating material has therein a plurality of damascene openings between each two neighboring linear stacks, wherein each damascene opening exposes a portion of each of the opposite sidewalls of all the channel layers of two neighboring linear stacks. The charge trapping layer is disposed on all sidewalls of each of the damascene openings. The word lines are disposed in the damascene openings, separated from the linear stacks by the charge trapping layer.

Because the word lines are formed in the damascene openings in the method for forming a 3D memory of this invention, word-line bridging can be prevented in the 3D memory of this invention formed with the above method.

In order to make the aforementioned and other objects, features and advantages of this invention comprehensible, a preferred embodiment accompanied with figures is described in detail below.

### BRIEF DESCRIPTION OF THE DRAWINGS

FIGS. 1 to 4 illustrate, in a perspective view, a method for forming a 3D memory according to a first embodiment of this invention, wherein FIG. 4 also illustrates the structure of the 3D memory according to the first embodiment of this invention.

FIGS. 5 to 6 illustrate, in a perspective view, a method for forming a 3D memory according to a second embodiment of this invention, wherein FIG. 6 also illustrates the structure of the 3D memory according to the second embodiment of this invention.

FIG. 7 illustrates, in a perspective view, an alternative way of forming the charge trapping layer in the method for forming a 3D memory according to a third embodiment of this invention.

### DESCRIPTION OF EMBODIMENTS

This invention is further explained with the following embodiments, which are not intended to limit the scope thereof. For example, although the stacked structure includes four semiconductor layers to form four levels of memory cells in the following embodiments, the stacked structure may alternatively include two, three or more than four semiconductor layers to form two, three or more than four levels of memory cells in other embodiments.

FIGS. 1 to 4 illustrate, in a perspective view, a method for forming a 3D memory according to a first embodiment of this invention, wherein FIG. 4 also illustrates the structure of the 3D memory according to the first embodiment of this invention.

Referring to FIG. 1, a substrate 10 is provided, which may be a semiconductor substrate such as a silicon substrate, or a glass substrate. A stacked structure 12, which includes a plurality of semiconductor layers 16 and a plurality of insulating layers 14 arranged alternately, is formed on the substrate 10. The semiconductor layers 16 may include poly-Si or Ge. The insulating layers 14 may include silicon oxide or SiOCH. A hard mask layer 18, which may include silicon nitride (SiN) or SiO₂, is then formed on the stacked structure 12.

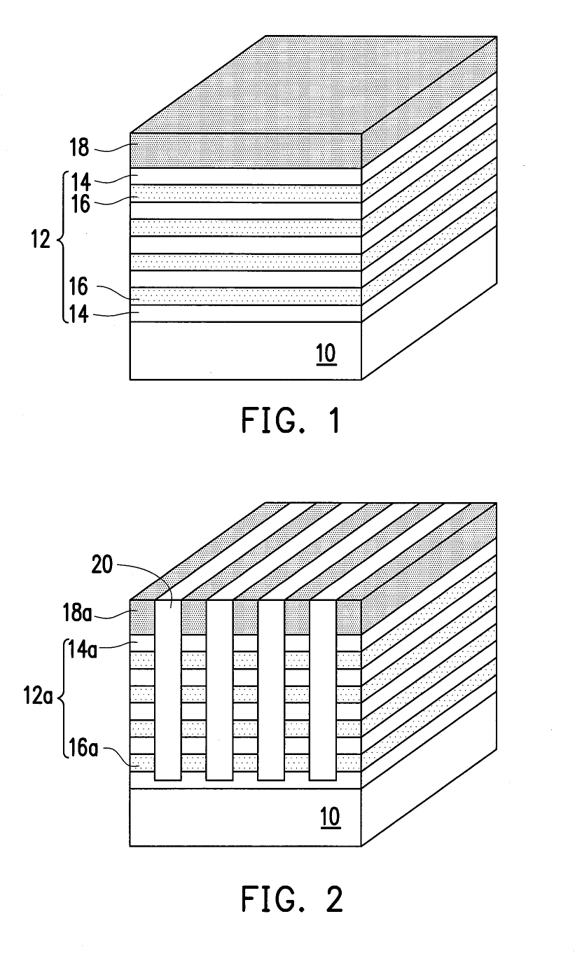

Referring to FIG. 2, the stacked structure 12 is patterned into a plurality of linear stacks 12a in a row direction, wherein each linear stack 12a includes a plurality of channel layers 16a and a plurality of linear insulators 14a arranged alternately, and has a linear hard mask part 18a left thereon. An insulating material 20 is then filled in between the linear stacks 12a and also between the linear hard mask parts 18a, possibly by depositing a layer of the insulating material filling up the gaps between the linear stacks 12a and then removing the portion of the same outside of the gaps by, e.g., chemical mechanical polishing (CMP). The insulating material 20 may include silicon oxide or SiOCH.

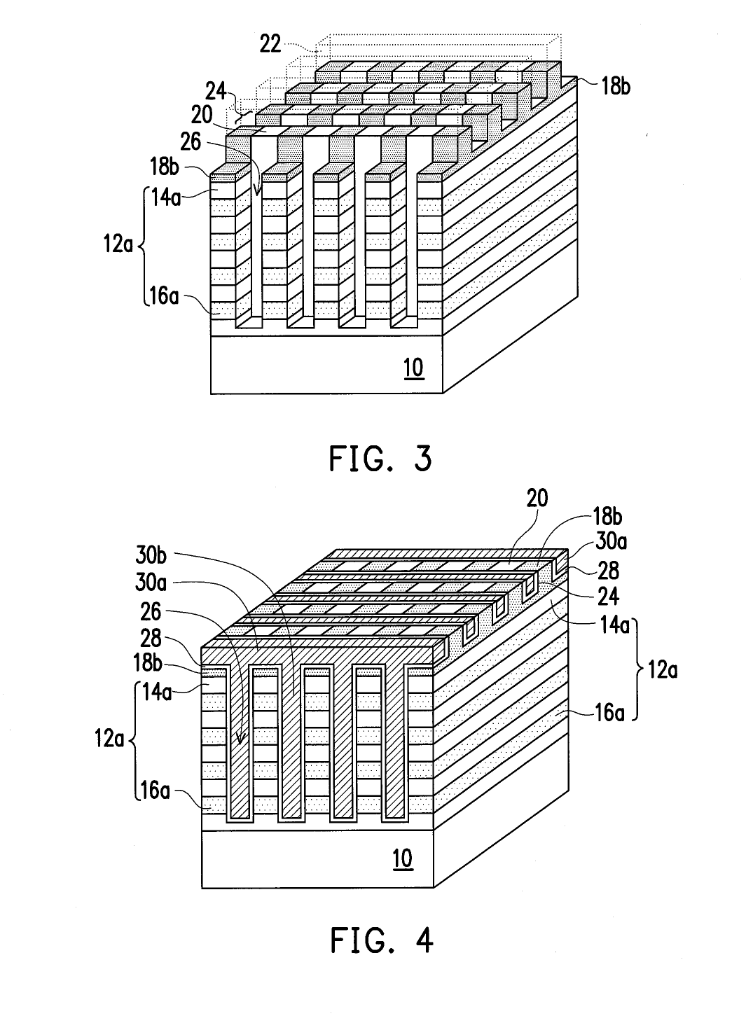

Referring to FIG. 3 in combination with FIG. 2, a patterned mask layer including a plurality of photoresist lines 22 in a column direction is formed over the linear hard mask parts 18a (see FIG. 2) and the insulating material 20. Anisotropic etching is then conducted to form a plurality of trenches 24 in the column direction through the linear hard mask parts 18a and the insulating material 20, and simultaneously form a plurality of damascene openings 26 in the insulating material 20 between each two neighboring linear stacks 12a. The linear hard mask parts 18a become uneven linear hard mask parts 18b after the trenches 24 are formed.

Each damascene opening 26 exposes a portion of each of the opposite sidewalls of all the channel layers 16a of two neighboring linear stacks 12a. Each trench 24 is contiguous with a column of damascene openings 26. Such dual damascene structure may result from an etching recipe that makes the etching rate of the insulting material 20 several times higher than the etching rate of the hard mask layer 18. In addition, the photoresist lines 22 may be all consumed in the anisotropic etching, or a residue of the photoresist lines 22 is stripped away after the anisotropic etching is finished.

Referring to FIG. 4, a charge trapping layer 28 is formed in each of the trenches 24 and also in each of the damascene openings 26. The charge trapping layer 28 may include a silicon oxide/SiN/silicon oxide (ONO) composite layer, or a Hf-based material. A conductive layer (30a+30b) is then filled in the trenches 24 and also in the damascene openings 26 to form a plurality of interconnect lines 30a in the trenches 24 and a plurality of word lines 30b in the damascene openings 26, wherein each interconnect line 30a is connected with a column of word lines 30b. The charge trapping layer 28 and the conductive layer (30a+30b) may be formed by forming a substantially conformal blanket charge trapping layer and a conductive material filling up the trenches 24 and the damascene openings 26 and then removing the portions of the conductive material and the blanket charge trapping layer outside of the trenches 24 possibly by CMP. The interconnect lines 30a and the word lines 30b may include doped poly-Si or tungsten.

Though the interconnect lines for the word lines are formed simultaneously with the word lines in a dual damascene process in the first embodiment, it is possible to form the interconnect lines and the word lines in two steps alternatively, as described in the following second embodiment.

FIGS. 1 to 6 illustrate, in a perspective view, a method for forming a 3D memory according to the second embodiment of this invention, wherein FIG. 6 also illustrates the structure of the 3D memory according to the second embodiment of this invention.

The formations and/or materials of the stacked structure 12, the hard mask layer 18, the linear stacks 12a, the insulating material 20, the trenches 24, the damascene openings 26 and so on are as described above and as illustrated in FIGS. 1 to 3.

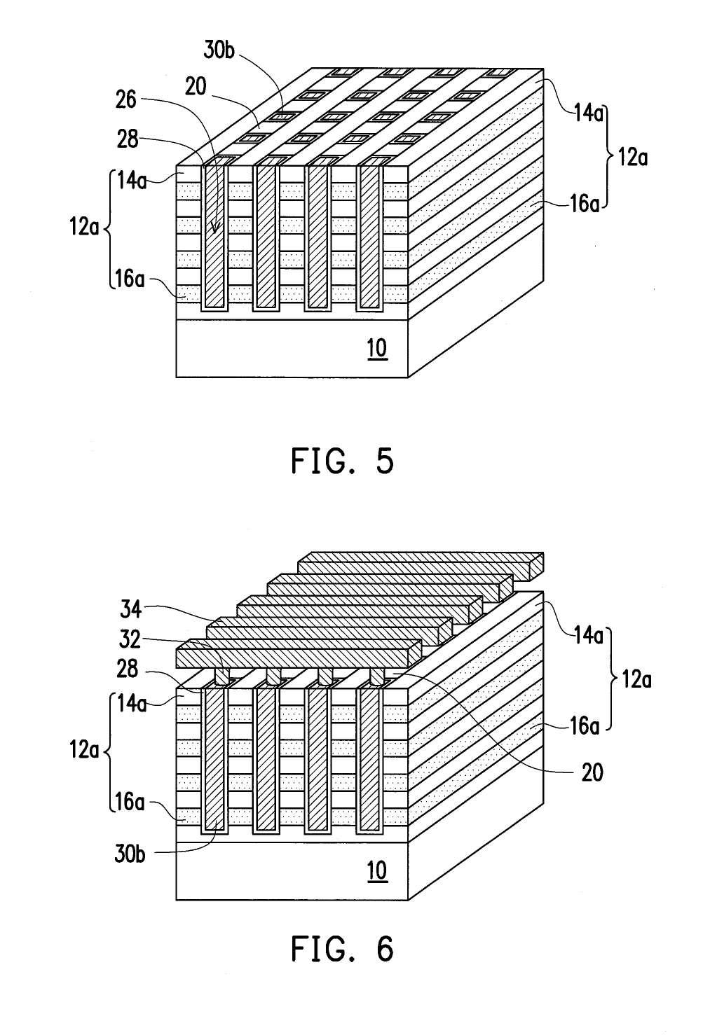

Referring to FIGS. 4 and 5, in this embodiment, the removal process (possibly by CMP) for separating the interconnect lines 30a in the first embodiment is not stopped on the linear hard mask parts 18b, but is continued after the linear hard mask parts 18b are exposed and finally stopped on the upmost ones of the linear insulators 14a. That is, the linear hard mask parts 18b, a portion of the insulating material 20, a portion of the charge trapping layer 28, the lines 30a (not interconnect lines in this embodiment) in the trenches 24 and a portion of each of the word lines 30b in the damascene openings 26 that are higher than the tops of the linear stacks 12a are removed (by CMP). Briefly speaking, anything higher than the tops of the linear stacks 12a is removed (by CMP).

Referring to FIG. 6, a plurality of contact plugs 32 and a plurality of interconnect lines 34 in the column direction are formed over the word lines 30b, wherein each interconnect line 34 is electrically connected with a column of word lines 30b via a column of contact plugs 32. The contact plugs 32 and the interconnect lines 34 may be formed with a dual damascene process. The contact plugs 32 may include tungsten. The interconnect line 34 may include Cu or AlCu.

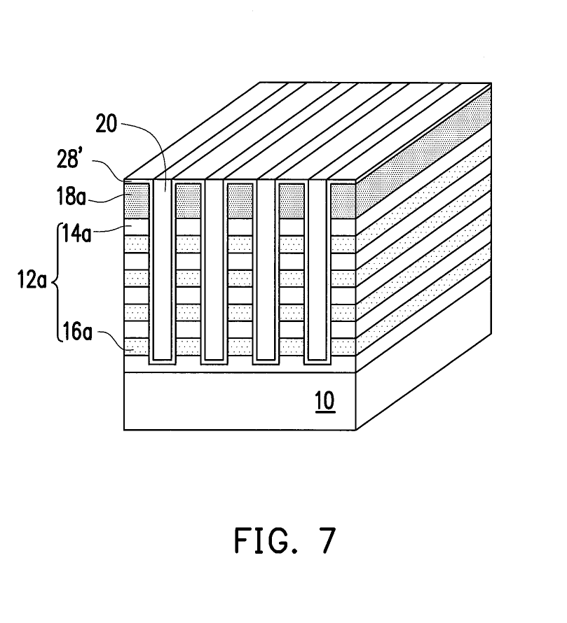

In addition, although in the above embodiments the charge trapping layer (28) is formed in the damascene openings (26) after the damascene openings (26) are formed but before the word lines (30b) are formed, in other embodiments, the charge trapping layer may alternatively be formed after the stacked structure (12) is patterned into the linear stacks (12a) but before the insulating material (20) is filled in between the linear stacks (12a). This is illustrated in FIG. 7 as a third embodiment of this invention.

Referring to FIG. 7, after the stacked structure 12 is patterned into the linear stacks 12a, a substantially conformal charge trapping layer 28′ is formed covering the resulting structure, and then the insulating material 20 is filled in between the linear stacks 12a and also between the linear hard mask parts 18a while being separated from the linear stacks 12a and the linear hard mask parts 18a by the charge trapping layer 28′. The material of the charge trapping layer 28′ may be the same as that of the charge trapping layer 28 mentioned in the above first and second embodiments.

After the charge trapping layer 28′ and the insulating material 20 are formed, the trenches 24, the damascene openings 26, the interconnect lines 30a and the word lines 30b (FIGS. 3 and 4), or the trenches 24, the damascene openings 26, the word lines 30b and the interconnect line 34 (FIGS. 3 to 6), may be formed as in the above first or second embodiment.

Because the word lines are formed in the damascene openings in the methods for forming a 3D memory of the above embodiments of this invention, word-line bridging can be prevented in the 3D memory of the above embodiments formed with the above methods.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A method for forming a three-dimensional (3D) memory, comprising:
forming on a substrate a stacked structure comprising a plurality of semiconductor layers and a plurality of insulating layers arranged alternately;
patterning the stacked structure into a plurality of linear stacks in a row direction, wherein each linear stack comprises a plurality of channel layers and a plurality of linear insulators arranged alternately, the channel layers are defined from the semiconductor layers, and the linear insulators are defined from the insulating layers;
filling an insulating material in between the linear stacks;
forming a plurality of damascene openings in the insulating material between each two neighboring linear stacks, wherein each damascene opening exposes a portion of each of opposite sidewalls of all the channel layers of two neighboring linear stacks;
forming a charge trapping layer; and
forming a word line in each of the damascene openings.

2. The method of claim 1, wherein the damascene openings are defined by a plurality of photoresist lines oriented in a column direction.

3. The method of claim 1, further comprising:
forming a hard mask layer on the stacked structure and patterning the hard mask layer into a plurality of linear hard mask parts in the row direction before the stacked structure is patterned;
also filling the insulating material in between the linear hard mask parts in the step of filling the insulating material in between the linear stacks;
also forming a plurality of trenches in a column direction in the patterned hard mask layer and the insulating material in the step of forming the damascene openings, wherein each trench is contiguous with a column of damascene openings; and
also forming a plurality of interconnect lines in the trenches in the step of forming a word line in each of the damascene openings, wherein a material of the interconnect lines is the same as a material of the word lines, and each interconnect line is connected with a column of word lines.

4. The method of claim 1, further comprising forming a plurality of contact plugs and a plurality of interconnect lines in a column direction over the word lines, wherein each interconnect line is electrically connected with a column of word lines via a column of contact plugs.

5. The method of claim 4, further comprising:
forming a hard mask layer on the stacked structure and patterning the hard mask layer into a plurality of linear hard mask parts in the row direction before the stacked structure is patterned;
also filling the insulating material in between the linear hard mask parts in the step of filling an insulating material in between the linear stacks; and
removing anything higher than tops of the linear stacks, after the word lines are formed but before the contact plugs and the interconnect lines are formed.

6. The method of claim 5, further comprising:
also forming a plurality of trenches in the column direction in the patterned hard mask layer and the insulating material in the step of forming the damascene openings, wherein each trench is contiguous with a column of damascene openings;
also forming a plurality of lines in the trenches in the step of forming the word lines in the damascene openings, wherein a material of the lines is the same as a material of the word lines, and each line is connected with a column of word lines; and.
also removing the lines in the trenches in the step of removing anything higher than the linear stacks.

7. The method of claim 5, wherein the step of removing anything higher than the tops of the linear stacks comprises a chemical mechanical polishing (CMP) process that is stopped on the tops of the linear stacks.

8. The method of claim 1, wherein the charge trapping layer is formed in the damascene openings after the damascene openings are formed but before the word lines are formed.

9. The method of claim 1, wherein the charge trapping layer is formed after the stacked structure is patterned into the linear stacks but before the insulating material is filled in between the linear stacks.

10. The method of claim 1, wherein the semiconductor layers comprise poly-Si.

11. The method of claim 1, wherein the insulating layers comprise silicon oxide.

12. The method of claim 1, wherein the insulating material comprises silicon oxide.

13. A three-dimensional (3D) memory, comprising:
a plurality of linear stacks in a row direction, wherein each linear stack comprises a plurality of channel layers and a plurality of linear insulators arranged alternately;
an insulating material between the linear stacks, having therein a plurality of damascene openings between each two neighboring linear stacks, wherein each damascene opening exposes a portion of each of opposite sidewalls of all the channel layers of two neighboring linear stacks;
a charge trapping layer on all sidewalls of each of the damascene openings; and
a plurality of word lines in the damascene openings, separated from the linear stacks by the charge trapping layer.

14. The 3D memory of claim 13, further comprising:
a patterned hard mask layer comprising a plurality of linear hard mask parts each disposed on a linear stack, wherein the insulating material is also filled in between the linear hard mask parts; and
a plurality of interconnect lines in a plurality of trenches in a column direction in the patterned hard mask layer and the insulating material, wherein each interconnect line is connected with a column of word lines.

15. The 3D memory of claim 13, further comprising:
a plurality of contact plugs over the word lines; and
a plurality of interconnect lines in a column direction over the contact plugs, wherein each interconnect line is electrically connected with a column of word lines via a column of contact plugs.

16. The 3D memory of claim 13, wherein the channel layers comprise poly-Si.

17. The 3D memory of claim 13, wherein the linear insulators comprise silicon oxide.

18. The 3D memory of claim 13, wherein the insulating material comprises silicon oxide.

19. The 3D memory of claim 13, wherein the charge trapping layer comprises an ONO composite layer.

20. The 3D memory of claim 13, wherein the word lines comprise poly-Si.
